(19) United States
(12) Patent Application Publication
(10) Pub. No.: US 2023/0375352 A1
(43) Pub. Date: Nov. 23, 2023

(54) METHOD FOR OPTIMIZING A SERVICE LIFE OF A DRIVE BATTERY

(71) Applicant: Robert Bosch GmbH, Stuttgart (DE)

(72) Inventors: Rolf Nicodemus, Bietigheim-Bissingen (DE); Stefan Nordbruch, Leonberg (DE)

(21) Appl. No.: 18/318,936

(22) Filed: May 17, 2023

(30) Foreign Application Priority Data
May 23, 2022 (DE) 10 2022 205 111.4

(51) Int. Cl. G01C 21/34; B60L 58/12; B60L 58/26

(52) U.S. Cl. CPC G01C 21/3469; B60L 58/12; B60L 58/26; B60L 2240/545

(57) ABSTRACT

A method for optimizing a service life of a drive battery of an electric motor vehicle. The method includes: receiving drive battery charging state signals representing a drive battery charging state of the drive battery; generating care suggestion signals based on the drive battery charging state signals and based on at least one recommendation for drive battery care to optimize a service life of the drive battery of the electric motor vehicle, wherein the care suggestion signals represent a care suggestion for caring for the drive battery; outputting the generated care suggestion signals. A device, a computer program and a machine-readable storage medium are also described.

### CROSS REFERENCE

The present application claims the benefit under 35 U.S.C. § 119 of German Patent Application No. DE 10 2022 205 111.4 filed on May 23, 2022, which is expressly incorporated herein by reference in its entirety.

### FIELD

The present invention relates to a method for optimizing a service life of a drive battery of an electric motor vehicle, to a device, a computer program and a machine-readable storage medium.

### BACKGROUND INFORMATION

Electric motor vehicles comprise a drive battery for supplying electrical power to their electric motor.

Such drive batteries are technically complex to produce.

There is thus a need to optimize a service life of a drive battery of an electric motor vehicle in order to be able to use it as long as possible.

### SUMMARY

An object of the present invention is to provide for efficiently optimizing a service life of a drive battery of an electric motor vehicle.

This object may be achieved by the present invention. Advantageous embodiments of the present invention are disclosed herein.

According to a first aspect of the present invention, a method for optimizing a service life of a drive battery of an electric motor vehicle is provided. According to an example embodiment of the present invention, the method comprises the following steps:
receiving drive battery charging state signals representing a drive battery charging state of the drive battery,
generating care suggestion signals based on the drive battery charging state signals and based on at least one recommendation for drive battery care to optimize a service life of the drive battery of the electric motor vehicle,
wherein the care suggestion signals represent a care suggestion for caring for the drive battery,
outputting the generated care suggestion signals.

According to a second aspect of the present invention, a device is provided, which is configured to carry out all steps of the method according to the first aspect of the present invention.

According to a third aspect of the present invention, a computer program is provided, which comprises instructions that, when the computer program is executed by a computer, for example by the device according to the second aspect, cause said computer to carry out a method according to the first aspect of the present invention.

According to a fourth aspect of the present invention, a machine-readable storage medium is provided, on which the computer program according to the third aspect of the present invention is stored.

The present invention is based on, and includes, the finding that the above object is achieved by ascertaining a care suggestion for caring for the drive battery of the electric motor vehicle based on the charging state of the drive battery and based on at least one recommendation for drive battery care. By using at least one recommendation for drive battery care to optimize a service life of the drive battery of the electric motor vehicle, it is possible to efficiently ascertain a care suggestion for caring for the drive battery that is suitable to efficiently optimize the service life of the drive battery of the electric motor vehicle when the care suggestion is implemented.

This in particular brings about the technical advantage that a service life of a drive battery of an electric motor vehicle can be optimized. Consequently, a concept for efficiently optimizing a service life of a drive battery of an electric motor vehicle is provided.

A drive battery, which may also be referred to as a high-voltage store, traction battery or cycle battery, is in particular an accumulator, which is in particular primarily intended to supply electrical energy to the propulsion-providing electric motor of the electric motor vehicle.

The phrase “at least one” means “one or more.” This means that the phrase “at least one recommendation” means “one or more recommendations.” Thus, several recommendations may, for example, be provided, based on which the care suggestion signals are generated. Statements made in connection with a recommendation apply analogously to several recommendations, and vice versa.

Since the drive battery may be an accumulator, the term “accumulator care” may also be used for the term “drive battery care.”

In one embodiment of the method of the present invention, it is provided that the method comprises a step of implementing the care suggestion based on the output care suggestion signals.

This in particular brings about the technical advantage that the service life of the drive battery can be efficiently optimized.

In one embodiment of the method of the present invention, it is provided that route signals representing a route of the electric motor vehicle leading from a start position to a target position are received, wherein the care suggestion signals are generated based on the route signals.

This, for example, brings about the technical advantage that the care suggestion signals can be efficiently generated. According to this embodiment, it is thus provided that the route taken or to be taken by the electric motor vehicle is taken into account when ascertaining a suggestion for drive battery care. For example, it is true that full charging, i.e., charging up to a maximum possible drive battery charging state, of the drive battery is not necessarily conducive to a longevity of the drive battery. If, according to the route, the electric motor vehicle does not need a fully charged drive battery to reach a target position, the suggestion not to fully charge the battery can be output, for example.

If, for example, according to the route, the electric motor vehicle actually needs a full charge to reach its target position, but, according to the route, one or more charging stations, at which the drive battery can be charged, are located along the route, the suggestion that a full charge is not needed at the start of the trip from the start position can be output, for example. For example, the suggestion may comprise that one or more charging stations should be visited along the route to charge the drive battery accordingly there. A number of full charges can thus, for example, be avoided or at least reduced, which promotes a longevity of the drive battery so that a service life of a drive battery of an electric motor vehicle can be efficiently optimized in an efficient manner.

In one embodiment of the method of the present invention, it is provided that the at least one recommendation comprises a recommendation for a predetermined minimum drive battery charging state, wherein the drive battery charging state is compared to the predetermined minimum drive battery charging state, wherein if the drive battery charging state is less than, or less than or equal to, the predetermined minimum drive battery charging state, the care suggestion comprises charging the drive battery.

This, for example, brings about the technical advantage that an efficient care suggestion can be ascertained. Charging states of a drive battery that are too low can shorten a service life of the drive battery. Thus, by offering a suggestion, according to which the drive battery is to be charged if the charging state of the drive battery is less than, or less than or equal to, the predetermined minimum drive battery charging state, a reduction in a service life of the drive battery due to a charging state that is too low can thus be efficiently counteracted in an efficient manner.

In one embodiment of the method of the present invention, it is provided that the at least one recommendation recommends a recommendation for a predetermined maximum drive battery charging state, wherein the drive battery charging state is compared to the predetermined maximum drive battery charging state, wherein if the drive battery charging state is greater than, or greater than or equal to, the predetermined maximum drive battery charging state, the care suggestion comprises discharging the drive battery.

This, for example, brings about the technical advantage that a particularly efficient care suggestion can be ascertained. Analogously to the above embodiment with regard to the minimum drive battery charging state, it is also true that charging states that are too high can shorten a service life of the drive battery. Thus, by offering a suggestion to discharge the drive battery if the drive battery charging state is greater than, or greater than or equal to, the predetermined maximum drive battery charging state, a reduction in the service life of the drive battery due to charging states that are too high can be efficiently counteracted in an efficient manner.

According to one embodiment of the present invention, it is provided that rapid charging history signals representing a rapid charging history of the drive battery are received, wherein the at least one recommendation comprises a recommendation for use of rapid charges of the drive battery, wherein the rapid charging history is compared to the recommended use of rapid charges, wherein the care suggestion signals are generated based on the comparison.

This, for example, brings about the technical advantage that a particularly efficient care suggestion can be ascertained. Although, rapid charges have the advantage that the drive battery can be charged particularly quickly, too many rapid charges can accelerate an aging process of the drive battery so that a service life of the drive battery can be shortened thereby.

For example, the rapid charging history indicates a number of rapid charges already performed. For example, the recommendation for use of rapid charges states a recommended maximum number of rapid charges. The comparison of the rapid charging history to the recommended use of rapid charges comprises, for example, a comparison of the number of rapid charges already performed to the number of recommended rapid charges. If, for example, the number of rapid charges already performed is greater than, or greater than or equal to, the recommended number of rapid charges, the suggestion states to refrain from a further rapid charge, for example. Thus, the service life of the drive battery can be efficiently optimized in an advantageous manner.

In particular, a rapid charge refers to a charge according to which electrical energy was charged in a maximum of 30 minutes, which is usually sufficient for a trip of 200 km. In particular, a rapid charge refers to a charge at at least 20 kW, in particular at least 22 kW, in particular at least 43 kW, in particular at least 50 kW, in particular at least 100 kW, in particular at least 150 kW, in particular at least 250 kW, in particular 350 kW.

According to one embodiment of the method of the present invention, it is provided that rapid discharging history signals representing a rapid discharging history of the drive battery are received, wherein the at least one recommendation comprises a recommendation for use of rapid discharges, wherein the rapid discharging history is compared to the recommended use of rapid discharges, wherein the care suggestion signals are generated based on the comparison.

This, for example, brings about the technical advantage that a particularly efficient care suggestion can be ascertained. Although, rapid discharges have the advantage that the drive battery can be discharged particularly quickly, too many rapid discharges can accelerate an aging process of the drive battery so that a service life of the drive battery can be shortened thereby.

For example, the rapid discharging history indicates a number of rapid discharges already performed. For example, the recommendation for use of rapid discharges states a recommended maximum number of rapid discharges. The comparison of the rapid discharging history to the recommended use of rapid discharges comprises, for example, a comparison of the number of rapid discharges already performed to the number of recommended rapid discharges. If, for example, the number of rapid discharges already performed is greater than, or greater than or equal to, the recommended number of rapid discharges, the suggestion states to refrain from a further rapid discharge, for example. Thus, the service life of the drive battery can be efficiently optimized in an advantageous manner.

In particular, a rapid discharge refers to a discharge according to which electrical energy was discharged in a maximum of 30 minutes, which is usually sufficient for a trip of 200 km. In particular, a rapid discharge refers to a discharge at at least kW, in particular at least 22 kW, in particular at least 43 kW, in particular at least 50 kW, in particular at least 100 kW, in particular at least 150 kW, in particular at least 250 kW, in particular 350 kW.

In one embodiment of the method of the present invention, it is provided that ambient temperature signals representing an ambient temperature of the drive battery are received, wherein the recommendation comprises a predetermined ambient temperature range of the drive battery for charging and/or discharging the drive battery, wherein it is ascertained whether the ambient temperature is within the predetermined ambient temperature range, wherein the care suggestion signals are ascertained based thereon.

This, for example, brings about the technical advantage that a particularly efficient and effective care suggestion can be ascertained. Extreme temperatures can negatively impact a service life of the drive battery. This applies to both too high and too low temperatures. Both can, for example, result in a decrease in a charging capacity. By taking this circumstance into account in ascertaining the care suggestion, the service life of the drive battery can be optimized efficiently.

In one embodiment of the method of the present invention, it is provided that, if the ambient temperature is outside of the predetermined ambient temperature range, the care suggestion comprises activating a drive battery air conditioner of the electric motor vehicle in order to heat the drive battery in the case of an ambient temperature below the predetermined ambient temperature range and/or to cool the drive battery in the case of an ambient temperature above the predetermined ambient temperature range.

This, for example, brings about the technical advantage that a negative influence of the ambient temperature on the service life of the drive battery can be efficiently reduced or even avoided. This is because by activating the drive battery air conditioner to heat or cool the drive battery, a temperature for the drive battery can be reached that does not negatively affect the service life of the drive battery.

In one embodiment of the method of the present invention, it is provided that, if the ambient temperature is below the predetermined ambient temperature range, the suggestion comprises bringing or driving the electric motor vehicle to a location where the electric motor vehicle is protected from the ambient temperature. Such a place is, for example, a garage.

In one embodiment of the method of the present invention, it is provided that, if the ambient temperature is above the predetermined ambient temperature range, the suggestion comprises bringing the electric motor vehicle to a location where the electric motor vehicle is protected from the ambient temperature. Such a place is, for example, a shaded location, e.g., a garage.

In one embodiment of the method of the present invention, it is provided that slow charging history signals representing a slow charging history of the drive battery are received, wherein the at least one recommendation comprises a recommendation for use of slow charges, wherein the slow charging history is compared to the recommended use of slow charges, wherein the care suggestion signals are generated based on the comparison.

This, for example, brings about the technical advantage that the service life of the drive battery can be efficiently optimized by an effective and efficient care suggestion. Slow charges refer to charging processes in which the drive battery is, for example, charged at a predetermined maximum charging power and/or at a predetermined maximum charging current. Such a predetermined maximum charging current is, for example, max. 16 amperes. Such a predetermined maximum charging power is, for example, max. 3.5 kW.

With such slow charging processes, the drive battery can be particularly gently charged so that an aging process of the drive battery is delayed. The drive battery can thus remain operational and powerful for longer. Thus, the service life of the drive battery can be efficiently optimized in an advantageous manner.

The slow charging history indicates, for example, a number of slow charges already performed. The recommendation for use of slow charges comprises, for example, a minimum number of slow charges. If, for example, the number of slow charges already performed is less than the recommended number of slow charges, the suggestion states to perform a slow charge, for example.

According to one embodiment of the method of the present invention, it is provided that the slow discharging history signals representing a slow discharging history of the drive battery are received, wherein the at least one recommendation comprises a recommendation for recommended use of slow discharges, wherein the slow discharging history is compared to the recommended use of slow discharges, wherein the care suggestion signals are generated based on the comparison.

This, for example, brings about the technical advantage that the service life of the drive battery can be efficiently optimized.

Slow discharges refer to discharging processes in which the drive battery is, for example, discharged at a predetermined maximum discharging power and/or at a predetermined maximum discharging current. Such a predetermined maximum discharging current is, for example, max. 16 amperes. Such a predetermined maximum discharging power is, for example, max. 3.5 kW.

With such slow discharging processes, the drive battery can be particularly gently discharged so that aging process of the drive battery is delayed. The drive battery can thus remain operational and powerful for longer. Thus, the service life of the drive battery can be efficiently optimized in an advantageous manner.

The slow discharging history indicates, for example, a number of slow discharges already performed. The recommendation for use of slow discharges comprises, for example, a minimum number of slow discharges. If, for example, the number of slow discharges already performed is less than the recommended number of slow discharges, the suggestion states to perform a slow discharge, for example.

In one embodiment of the method of the present invention, it is provided that trip planning signals representing a future trip plan for the electric motor vehicle are received, wherein a duration of a planned standing time of the electric motor vehicle, in which, according to the future trip plan, the electric motor vehicle is not driven, is ascertained based on the trip planning signals, wherein the at least one recommendation comprises a recommendation for a standing time threshold value from which the drive battery charging state of the drive battery is to be within a predetermined drive battery charging state range at standstill of the electric motor vehicle, wherein it is ascertained whether the ascertained planned standing time is within the predetermined drive battery charging state range at standstill of the electric motor vehicle, wherein if the drive battery charging state is below the predetermined drive battery charging state range at standstill of the electric motor vehicle, the care suggestion comprises charging the drive battery until the drive battery charging state of the drive battery is within the predetermined drive battery charging state range at standstill of the electric motor vehicle, and/or wherein if the drive battery charging state is above the predetermined drive battery charging state range at standstill of the electric motor vehicle, the care suggestion comprises discharging the drive battery until the drive battery charging state of the drive battery is within the predetermined drive battery charging state range at standstill of the electric vehicle battery.

This, for example, brings about the technical advantage that a particularly efficient and effective care suggestion can be ascertained so that the service life of the drive battery can be efficiently optimized in an efficient manner.

It is true that, in order to slow down a power loss of the drive battery, it may be advantageous for the drive battery to have a charging state that is within the predetermined drive battery charging state range, provided the electric motor vehicle will not drive for an extended period of time.

According to this embodiment of the present invention, it is thus provided that the future trip plan is analyzed as to whether it includes a standing time. It is then ascertained how long this planned standing time is. If it is above the predetermined standing time threshold value, the suggestion may comprise discharging or charging the drive battery, depending on the drive battery charging state, in order to bring the drive battery charging state inside of the predetermined drive battery charging state range.

In one embodiment of the method of the present invention, it is provided that, in the event of a care suggestion comprising discharging the drive battery, the care suggestion comprises charging an off-board storage battery, in particular a household storage battery, with electrical energy generated based on the discharging of the drive battery.

This, for example, brings about the technical advantage that the electrical energy released by discharging the drive battery can be efficiently stored in the off-board storage battery so that the correspondingly stored electrical energy can be used further at a later date.

In one embodiment of the method of the present invention, it is provided that, in the event of a care suggestion comprising charging the drive battery, the care suggestion comprises charging the drive battery with electrical energy generated based on discharging an off-board storage battery, in particular a household storage battery.

This, for example, brings about the technical advantage that energy stored in an off-board storage battery can be used efficiently.

In one embodiment of the method of the present invention, it is provided that the method is a computer-implemented method.

Device features result analogously from corresponding method features, and vice versa. This means, in particular, that technical functionalities of the method result analogously from corresponding technical functionalities of the device, and vice versa.

In one embodiment of the method of the present invention, it is provided that the method is carried out by means of the device.

In one embodiment of the device of the present invention, it is provided that the device is programmatically configured to carry out all steps of the method according to the first aspect of the present invention.

The embodiments and exemplary embodiments described in the description may be combined with one another in any manner, even if this is not explicitly described.

The present invention is explained in more detail below using preferred exemplary embodiments.

### BRIEF DESCRIPTION OF THE DRAWINGS

FIG. 1 shows a flow chart of a method according to the first aspect of the present invention.

FIG. 2 shows a device according to the second aspect of the present invention.

FIG. 3 shows a machine-readable storage medium, according to an example embodiment of the present invention.

FIG. 4 shows a further device according to the second aspect of the present invention.

### DETAILED DESCRIPTION OF EXAMPLE EMBODIMENTS

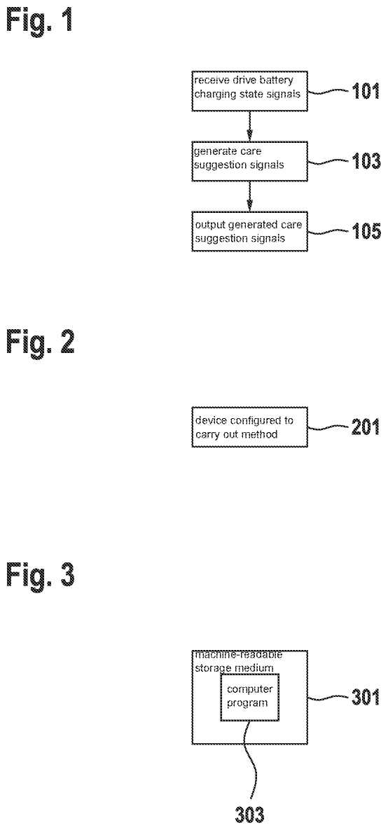

FIG. 1 shows a flow chart of a method for optimizing a service life of a drive battery of an electric motor vehicle, comprising the following steps:
receiving 101 drive battery charging state signals representing a drive battery charging state of the drive battery,
generating 103 care suggestion signals based on the drive battery charging state signals and based on at least one recommendation for drive battery care to optimize a service life of the drive battery of the electric motor vehicle,
wherein the care suggestion signals represent a care suggestion for caring for the drive battery,
outputting 105 the generated care suggestion signals.

A suggestion in the sense of the description is a care suggestion for caring for the drive battery.

FIG. 2 shows a device 201, which is configured to carry out all steps of the method according to the first aspect.

FIG. 3 shows a machine-readable storage medium 301, in which computer program 303 is stored. The computer program 303 comprises instructions that, when the computer program 303 is executed by a computer, cause the latter to carry out a method according to the first aspect.

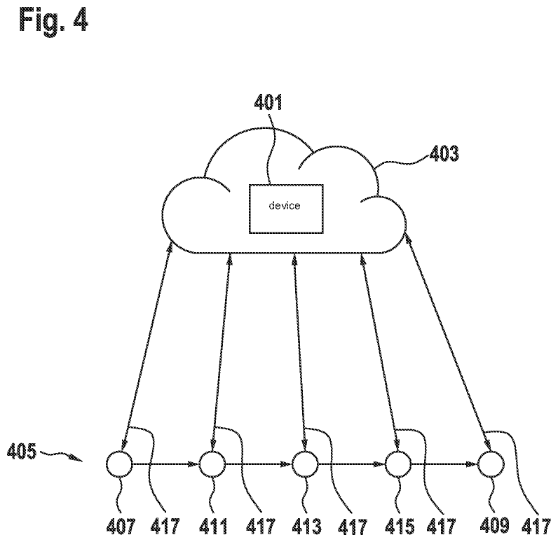

FIG. 4 shows a device 401 according to the second aspect. The device 401 is implemented in a cloud infrastructure 403. A route 405 of an electric motor vehicle comprising a drive battery leads from a start position 407 to a target position 409. The route 405 passes through a first intermediate position 411, a second intermediate position 413, and a third intermediate position 415. At these three intermediate positions 411, 413, 415, which can also be referred to as intermediate stations, the drive battery can be charged or discharged, for example. Furthermore, the drive battery can, for example, be charged or discharged at the start position 407 and/or at the target position 409.

This charging or discharging of the drive battery is performed in such a way that a service life of the drive battery is or can be optimized. The concept described herein is used. For example, a drive battery charging state of the drive battery is ascertained at each of the positions, wherein based thereon and based on at least one recommendation for drive battery care, a care suggestion for caring for the drive battery is ascertained. Based on the ascertained care suggestion, the charging or discharging of the drive battery is then performed at the individual positions 407 to 415.

The device 401 is in communication connection, symbolized by double arrows with reference sign 417, with charging stations (not shown) which are arranged or provided at the individual positions 407 to 415 and at which the drive battery can be charged or discharged. Thus, out of the cloud infrastructure 403, the device 401 can, for example, control the charging or discharging of the drive battery of the electric motor vehicle based on the ascertained care suggestion.

For example, it is provided that the device 401 is in communication connection with the electric motor vehicle. Thus, the electric motor vehicle sends the drive battery charging state to the device 401 via this communication connection, for example. Said device thus receives the drive battery charging state of the drive battery via the communication connection.

A communication connection is, for example, established or has been established via a communication network. A communication network comprises, for example, a WLAN communication network and/or a cellular network.

What is claimed is:

1. A method for optimizing a service life of a drive battery of an electric motor vehicle, comprising the following steps:
receiving drive battery charging state signals representing a drive battery charging state of the drive battery;
generating care suggestion signals based on the drive battery charging state signals and based on at least one recommendation for drive battery care to optimize a service life of the drive battery of the electric motor vehicle, wherein the care suggestion signals represent a care suggestion for caring for the drive battery; and
outputting the generated care suggestion signals.

2. The method according to claim 1, further comprising implementing the care suggestion based on the output care suggestion signals.

3. The method according to claim 1, wherein route signals representing a route of the electric motor vehicle leading from a start position to a target position are received, and wherein the care suggestion signals are generated based on the route signals.

4. The method according to claim 1, wherein the at least one recommendation includes a recommendation for a predetermined minimum drive battery charging state, wherein the drive battery charging state is compared to the predetermined minimum drive battery charging state, wherein when the drive battery charging state is less than, or less than or equal to, the predetermined minimum drive battery charging state, the care suggestion includes charging the drive battery.

5. The method according to claim 1, wherein the at least one recommendation recommends a recommendation for a predetermined maximum drive battery charging state, wherein the drive battery charging state is compared to the predetermined maximum drive battery charging state, wherein when the drive battery charging state is greater than, or greater than or equal to, the predetermined maximum drive battery charging state, the care suggestion includes discharging the drive battery.

6. The method according to claim 1, wherein rapid charging history signals representing a rapid charging history of the drive battery are received, wherein the at least one recommendation includes a recommendation for use of rapid charges of the drive battery, wherein the rapid charging history is compared to the recommended use of rapid charges, and wherein the care suggestion signals are generated based on the comparison.

7. The method according to claim 1, wherein rapid discharging history signals representing a rapid discharging history of the drive battery are received, wherein the at least one recommendation includes a recommendation for use of rapid discharges, wherein the rapid discharging history is compared to the recommended use of rapid discharges, and wherein the care suggestion signals are generated based on the comparison.

8. The method according to claim 1, wherein ambient temperature signals representing an ambient temperature of the drive battery are received, wherein the recommendation includes a predetermined ambient temperature range of the drive battery for charging and/or discharging the drive battery, wherein it is ascertained whether an ambient temperature is within the predetermined ambient temperature range, and wherein the care suggestion signals are ascertained based the ascertainment.

9. The method according to claim 8, wherein when the ambient temperature is outside of the predetermined ambient temperature range, the care suggestion includes activating a drive battery air conditioner of the electric motor vehicle in order to heat the drive battery when the ambient temperature is below the predetermined ambient temperature range and/or to cool the drive battery when the ambient temperature is above the predetermined ambient temperature range.

10. The method according to claim 1, wherein care suggestion slow charging history signals representing a slow charging history of the drive battery are received, wherein the at least one recommendation includes a recommendation for use of slow charges, wherein the slow charging history is compared to the recommended use of slow charges, and wherein the care suggestion signals are generated based on the comparison.

11. The method according to claim 1, wherein care suggestion slow discharging history signals representing a slow discharging history of the drive battery are received, wherein the at least one recommendation includes a recommendation for recommended use of slow discharges, wherein the slow discharging history is compared to the recommended use of slow discharges, and wherein the care suggestion signals are generated based on the comparison.

12. The method according to claim 1, wherein trip planning signals representing a future trip plan for the electric motor vehicle are received, wherein a duration of a planned standing time of the electric motor vehicle, in which, according to the future trip plan, the electric motor vehicle is not driven, is ascertained based on the trip planning signals, wherein the at least one recommendation includes a recommendation for a standing time threshold value from which the drive battery charging state of the drive battery is to be within a predetermined drive battery charging state range at standstill of the electric motor vehicle, wherein it is ascertained whether the ascertained planned standing time is within the predetermined drive battery charging state range at standstill of the electric motor vehicle, and wherein: i) when the drive battery charging state is below the predetermined drive battery charging state range at standstill of the electric motor vehicle, the care suggestion includes charging the drive battery until the drive battery charging state of the drive battery is within the predetermined drive battery charging state range at standstill of the electric motor vehicle, and/or ii) when the drive battery charging state is above the predetermined drive battery charging state range at standstill of the electric motor vehicle, the care suggestion includes discharging the drive battery until the drive battery charging state of the drive battery is within the predetermined drive battery charging state range at standstill of the electric vehicle battery.

13. The method according to claim 1, wherein when the care suggestion includes discharging the drive battery, the care suggestion includes charging an off-board storage battery with electrical energy generated based on the discharging of the drive battery.

14. The method according to claim 1, wherein when the care suggestion includes charging the drive battery, the care suggestion includes charging the drive battery with electrical energy generated based on discharging an off-board storage battery.

15. A device configured to optimize a service life of a drive battery of an electric motor vehicle, the device being configured to:
receive drive battery charging state signals representing a drive battery charging state of the drive battery;
generate care suggestion signals based on the drive battery charging state signals and based on at least one recommendation for drive battery care to optimize a service life of the drive battery of the electric motor vehicle, wherein the care suggestion signals represent a care suggestion for caring for the drive battery; and
output the generated care suggestion signals.

16. A non-transitory machine-readable storage medium on which is stored a computer program for optimizing a service life of a drive battery of an electric motor vehicle, the computer program, when executed by a computer, causing the computer to perform the following steps:
receiving drive battery charging state signals representing a drive battery charging state of the drive battery;
generating care suggestion signals based on the drive battery charging state signals and based on at least one recommendation for drive battery care to optimize a service life of the drive battery of the electric motor vehicle, wherein the care suggestion signals represent a care suggestion for caring for the drive battery; and
outputting the generated care suggestion signals.
